(19) United States
(12) Patent Application Publication
(10) Pub. No.: US 2012/0106112 A1
(43) Pub. Date: May 3, 2012

(54) Method for Producing an Electrical Circuit and Electrical Circuit

(75) Inventors: Sonja Knies, Rutesheim (DE); Ricardo Ehrenpfordt, Korntal-Muenchingen (DE)

(73) Assignee: Robert Bosch GmbH, Stuttgart (DE)

(21) Appl. No.: 13/283,378

(22) Filed: Oct. 27, 2011

(30) Foreign Application Priority Data
Oct. 27, 2010 (DE) 10 2010 042 987.2

(51) Int. Cl. H05K 3/40; H05K 3/42; H05K 3/36; H05K 7/06

(52) U.S. Cl. 361/783; 29/874; 29/852; 29/830

(57) ABSTRACT

A method for producing an electrical circuit includes providing a main printed circuit board having a plurality of metalized plated-through holes through the main printed circuit board along at least one separating line between adjacent printed circuit board regions of the main printed circuit board. Each printed circuit board region has electrical contact connection pads on at least the main surface of the printed circuit board region that is to be populated, electrical lines for connection between the plurality of plated-through holes and the contact connection pads, and at least one semiconductor chip electrically contact-connected by means of the contact connection pads. The main printed circuit board is covered with a potting compound across the printed circuit board regions with the semiconductor chips.

This application claims priority under 35 U.S.C. §119 to German patent application no. 10 2010 042 987.2, filed on Oct. 27, 2010 in Germany, the disclosure of which is incorporated herein by reference in its entirety.

### BACKGROUND

The present disclosure relates to a method for producing an electrical circuit, to an electrical circuit and to a sensor module comprising the electrical circuit.

Known surface-micromechanical (SMM) inertial sensors consist of a sensor chip having movable structures and a so-called cap above the moved structures and bonding pad regions on the plane of the moved structures. The construction technique in the so-called package or premold package or mold package is conventionally effected horizontally by mechanically fixing the separated chip by means of adhesive bonding and electrical contact-connection by means of wire bonding. The sensing direction(s) of the sensor module correspond to that (those) of the SMM sensor chip in the case of this construction technique. In order to change the sensing direction given by the sensor chip in the product, such that a different axis is measured, it is necessary conventionally to have recourse to construction techniques which are more complicated or more expensive in comparison with normal standard mold packages such as SOICs (Small-Outline Integrated Circuits) or LGAs (Land Grid Arrays).

DE 19521712 A1 describes a device for detecting an acceleration. In the device, a covering is installed on a housing body part in order to form a hollow part. A sensor chip, which is subjected to an acceleration and displaced, is bonded onto the hollow part and fixed within the latter. The housing body part is fixed substantially perpendicularly on a circuit board.

### SUMMARY

Against this background, the present disclosure presents a method for producing an electrical circuit, an electrical circuit and a sensor module as set forth below. Advantageous configurations emerge from the following description set forth below.

The disclosure is based on the insight that through the use of plated-through holes in an LGA substrate (LGA=Land Grid Array), instead of the normal LGA soldering pads or contact-connecting areas for soldering thereon, in an advantageous manner, it is possible to realize orthogonal mounting of LGA packages, preferably of direction-dependent sensors in the LGA package, in order to change the sensing direction thereof by means of the construction technique. Said plated-through holes then constitute a mechanical contact-connection and the electrical signal connections toward the outside and are situated on a side area of the LGA substrate after the separation of the package from the mold assemblage.

In this case, the through contacts simultaneously also serve as soldering locations for the vertical mounting of the package. Therefore, they fulfill a dual function. Consequently, steps of through-plating, separating and utilizing the separated through contacts as lateral connections enable the package to be applied to a carrier substrate substantially at an angle of 90°.

The advantages of the features of the disclosure are that perpendicular positioning and stable fixing of the LGA are possible without new processes. This is achieved in a very cost-effective manner by means of a skilful arrangement or a skilful layout of the substrate using the abovementioned plated-through holes having the dual function. Through contacts in printed circuit boards are established in printed circuit board production and can thus be produced expediently. The LGA technology is likewise known and optimized in terms of process engineering and therefore is very cost-effective. Advantageously, only a small number of additional or modified process steps are required in comparison with the most cost-effective LGA mass production process. Consequently, the method according to the disclosure makes it possible to provide, in an efficient and cost-effective manner, electrical circuits which find application in a sensor module, in order to enable detection in all three spatial directions.

The basic concept of using divided plated-through holes in the edge region of a substrate of a circuit as external contacts of the circuit is in this case not limited to the field of sensor technology, but rather can also be used in other fields of application.

The present disclosure provides a method for producing an electrical circuit, comprising the following steps:

Providing a main printed circuit board having a plurality of metalized plated-through holes through the main printed circuit board along at least one separating line between adjacent printed circuit board regions of the main printed circuit board, wherein each printed circuit board region has electrical contact connection pads on at least the main surface of the printed circuit board region that is to be populated, electrical lines for connection between the plurality of plated-through holes and the contact connection pads, and at least one semiconductor chip electrically contact-connected by means of the contact connection pads, wherein the main printed circuit board is covered with a potting compound across the printed circuit board regions with the semiconductor chips; and

dividing the main printed circuit board along the at least one separating line, wherein the plated-through holes are divided along the separating line in order to form external connections of the electrical circuit.

The correspondingly populated main printed circuit board can be provided as a finished part. Alternatively, the step of providing can comprise a plurality of method steps such as applying the contact connection pads, the electrical lines and also the semiconductor chips to the main printed circuit board, and producing the plated-through holes. The LGAs can be manufactured in the typical multiple panel of the printed circuit board manufacturers. An electrical circuit can be understood to be an integrated circuit having one or a plurality of electronic components. The electrical circuit can be provided in the form of an LGA (Land Grid Array) or LGA package. The circuit can have a layered construction. In order to produce the circuit, firstly two or more, typically a plurality of electrical circuits can be formed in an assemblage on and/or in the main printed circuit board. The main printed circuit board can be a substrate composed of a suitable material known in the field of the construction and connection technology. The main printed circuit board has a plurality of printed circuit board regions. A printed circuit board region corresponds to a section of the main printed circuit board in which an electrical circuit is respectively formed. In the printed circuit board regions, the contact connection pads for an electrical connection to the at least one semiconductor chip and the metalized plated-through holes for circuit-external contact-connections are arranged on at least the main surface of the main printed circuit board that is to be populated. A semiconductor chip can be a semiconductor device, for example a silicon chip. In this case, the circuit can have one or a plurality of semiconductor chips and also further electrical components. The semiconductor chip can be provided with contact connections for contact to be made by the contact connection pads. Components of the circuit are in each case enveloped by the potting compound. The separating line constitutes the line along which adjacent printed circuit board regions are separated or divided in order to form individual electrical circuits from the main printed circuit board. In this case, the separating line can divide the plurality of metalized plated-through holes substantially centrally in each case. Consequently, two printed circuit board regions in each case share a plurality of plated-through holes along a separating line between the two printed circuit board regions. In the process of dividing the main printed circuit board along the at least one separating line, the plated-through holes are likewise severed. Dividing is also designated as separating. In this case, the main printed circuit board is sawn, for example, along the separating lines or divided in some other way as is known in the field. The circuit can be soldered on the external connections formed by the divided plated-through holes.

In this case, dividing can be effected such that metalized plated-through hole segments extending over an entire thickness of the main printed circuit board in each case remain at printed circuit board regions adjacent to a separating line. Metalized plated-through hole segments or plated-through hole halves can be understood to be metalized semicylindrical cutouts in at least one side surface of the electrical circuit which arise from the metalized plated-through holes after dividing.

In this case, the plated-through hole halves need not be exact halves on account of production tolerances and an intended layout. This affords the advantage that by means of a single step of dividing from one set of plated-through holes two sets of external connections in the form of plated-through hole halves for two electrical circuits arise. Consequently, the method is further simplified and more efficient.

In accordance with one embodiment, in the step of providing, an electrically conductive material can be used for forming the plurality of metalized plated-through holes. In this case, the electrically conductive material can completely fill the plurality of metalized plated-through holes at least in end regions of the plated-through holes on the main surface of the main printed circuit board that is to be populated with the contact connection pads. The electrically conductive material can constitute the metalization of the plated-through holes and can be introduced into passage holes provided for the plated-through holes. The metalization can be a coating of the inner surface of the plated-through holes with an electrically conductive material, e.g. copper. In this embodiment, a thickness of the metalization can vary with regard to a length of the plated-through holes and range for example from a thin layer or edge metalization up to a complete filling of the plated-through holes. A region of complete filling can be formed at an end of a plated-through hole which is arranged at the main surface of the main printed circuit board that is on the semiconductor chip side, that is to say the main surface that is to be populated. The degree of filling of a plated-through hole with the electrically conductive material can vary across a length of a plated-through hole, or be constant. The complete filling at least one end of a plated-through hole affords protection against ingress of the potting compound used for encapsulating the circuit.

Consequently, the metalized plated-through holes can be completely filled with an electrically conductive material, such that the plated-through hole segments in each case have the form of a circle segment. In a step of applying, a solderable material can be applied to the metalized plated-through hole segments. The applying step can take place after separating. Solderable material can be understood to be a soldering agent, for example a metal alloy. This affords the advantage that a mechanical connection of the electrical circuit to a carrier structure can be produced in an uncomplicated manner using the solderable material.

In accordance with one embodiment, in the step of providing, a solderable material can be used for forming the plurality of metalized plated-through holes. Furthermore, the metalized plated-through holes can be shaped in a ring-shaped fashion, such that the plated-through hole segments in each case have the form of an annulus segment. Consequently, the solderable material can fill the plurality of metalized plated-through holes incompletely, such that a respective cavity remains in the plurality of metalized plated-through holes. By way of example, the plated-through holes can be embodied with a combination of electrically conductive material and a further additionally solderable material, but cannot be filled completely in this case. Applying the solderable material when producing the plated-through holes, that is to say before the dividing step, affords the advantage that it is no longer necessary for the solderable material to be applied subsequently.

In the step of providing, a temporary filling material can be filled into the plurality of metalized plated-through holes or a covering of the plurality of metalized plated-through holes is formed on the side of the main surface of the main printed circuit board that is to populated with the contact connection pads before the printed circuit board regions with the semiconductor chips are covered with the potting compound. The covering of the plated-through holes can have a layer, for example a film-like resist layer such as e.g. composed of patternable solid resist or some other suitable material from printed circuit board manufacture. The temporary material is removed again after the encapsulation of the circuit. This affords the advantage that no potting compound can penetrate into cavities of the plated-through holes and, consequently, no impairment of an electrical and/or mechanical contact-connectable in the region of the plated-through holes occurs. Therefore, removal of penetrated potting compound from the plated-through holes is advantageously obviated. In this case, a potting compound can be understood to be a molding material, a molding compound, also known as mold compound. The temporary material can be chosen such that it decomposes into gaseous products without any residues at relatively high temperatures. A material that dissolves in water during the separating step is also conceivable.

The present disclosure furthermore provides an electrical circuit, comprising the following features:

a printed circuit board, which has electrical contact connection pads on at least the main surface of the printed circuit board that is to be populated, a plurality of metalized plated-through hole segments along an edge area of the printed circuit board for forming external connections of the electrical circuit and electrical lines for connection between the plurality of plated-through hole segments and the contact connection pads of the printed circuit board;
at least one semiconductor chip, which is fitted to the main surface of the printed circuit board that is to be populated, and is electrically contact-connected by means of the contact connection pads; and
a potting compound, which covers the printed circuit board across the semiconductor chip.

The electrical circuit can be produced by means of the method according to the disclosure. In contrast to a conventional LGA having planar contact areas on the underside, the contact area can consist of a plated-through hole half having a cross section that is semicircular or constitutes a circle segment.

In this case, the at least one semiconductor chip can have a sensor element. In this case, a sensor element can be understood to be, for example, an inertial sensor that serves for detecting an acceleration force or a rate of rotation. If a plurality of semiconductor chips are present, it is not necessary for each chip to have a sensor element. This affords the advantage that as a result of the orthogonal mountability of an electrical circuit according to the disclosure on a carrier structure, the detection direction of the sensor element can be changed in a simple manner.

The present disclosure furthermore provides a sensor module, comprising the following features:

a carrier substrate with connection contacts; and
at least one electrical circuit according to the disclosure, wherein the plurality of plated-through hole segments are electrically and mechanically connected to the connection contacts of the carrier substrate, and wherein the main surface of the printed circuit board of the at least one electrical circuit is oblique or orthogonal with respect to a main surface of the carrier substrate.

In this case, a sensor module can be understood to be, for example, an arrangement composed of at least one electrical circuit according to the disclosure with a sensor element and composed of a carrier substrate. At least one electrical circuit according to the disclosure can advantageously be used in the sensor module. The electrical and mechanical connection between the connection contacts and the circuit can be effected in the context of and in accordance with SMT mounting known in the field (SMT=Surface-Mounting Technology). The sensor module can be provided for detecting acceleration forces or rates of rotation. On the carrier substrate of the sensor module, in addition to the electronic circuit according to the disclosure with the sensor element, it is also possible to fit a further circuit with a sensor element in a conventional manner. In this case, a main surface of the further circuit has approximately the same orientation as the main surface of the carrier substrate.

In accordance with one particular embodiment, two electrical circuits according to the disclosure can be connected to the carrier substrate, wherein the main surfaces of the printed circuit boards of the two electrical circuits are orthogonal with respect to one another and with respect to the main surface of the carrier substrate. In the present context, orthogonal means orthogonal within the scope of process-inherent tolerance limits. This affords the advantage that a sensor module having electrical circuits arranged in this way with sensor elements, such that detection of e.g. acceleration forces in more than one spatial direction is possible, can be produced with low structural outlay.

The present disclosure furthermore provides a method for producing a sensor module, comprising the following steps:

providing a carrier substrate with connection contacts;
providing at least one electrical circuit according the disclosure; and
soldering the plurality of plated-through hole segments of the at least one electrical circuit with the connection contacts of the carrier substrate, wherein the main surface of the printed circuit board of the at least one electrical circuit is oblique or orthogonal with respect to a main surface of the carrier substrate.

In this case, the at least one electrical circuit may have been produced in accordance with an embodiment of a method according to the disclosure.

### BRIEF DESCRIPTION OF THE DRAWINGS

The disclosure is explained in greater detail below by way of example with reference to the accompanying drawings, in which:

FIG. 1 shows a sectional view of an electrical circuit;

FIG. 2A shows a plan view and FIG. 2B a sectional view of an assemblage of two main printed circuit boards that have not yet been divided, in accordance with one exemplary embodiment of the present disclosure;

FIG. 3 shows a sectional view of two divided electrical circuits in accordance with one exemplary embodiment of the present disclosure;

FIG. 4 shows a side view of an electrical circuit in accordance with one exemplary embodiment of the present disclosure;

FIGS. 5 and 5B in each case show a sectional view of a carrier substrate and of an electrical circuit fitted thereto in accordance with one exemplary embodiment of the present disclosure;

FIG. 6A shows a plan view and FIG. 6B a sectional view of an assemblage of two electrical circuit that have not yet been divided, in accordance with one exemplary embodiment of the present disclosure;

FIG. 7A shows a plan view and FIG. 7B a sectional view of an assemblage of two electrical circuit that have not yet been divided, in accordance with one exemplary embodiment of the present disclosure; and

FIG. 8 shows a flow chart of a method in accordance with one exemplary embodiment of the present disclosure.

### DETAILED DESCRIPTION

In the following description of preferred exemplary embodiments of the present disclosure, identical or similar reference symbols are used for the elements that are illustrated in the various figures and act in a similar fashion, a repeated description of these elements being dispensed with.

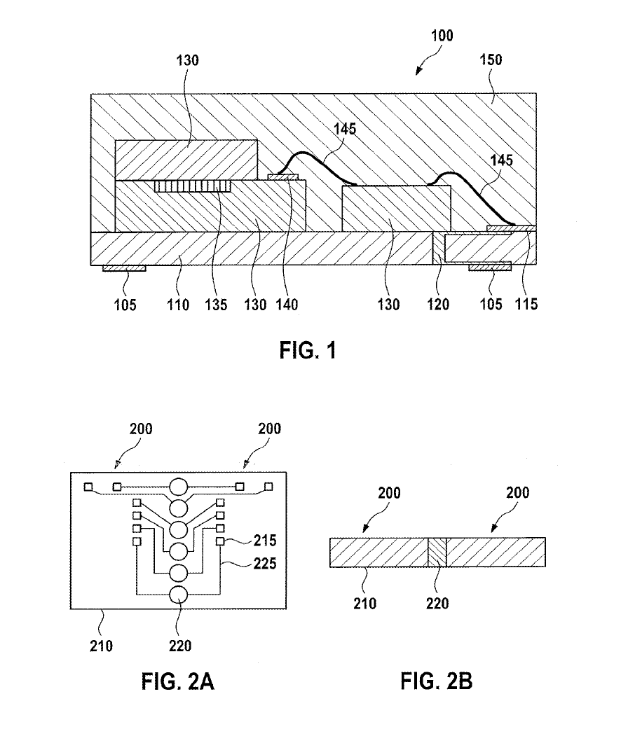

FIG. 1 shows a sectional view of an electrical circuit 100, to put it more precisely a schematic cross section of a standard LGA package. The electrical circuit 100 comprises soldering pads 105, a printed circuit board 110, a contact connection pad 115, a plated-through hole 120, semiconductor chips 130, a micromechanical sensor core 135, a chip contact area 140, bonding wires 145 and a potting compound 150. The semiconductor chips 130 can have a sensor chip and an evaluation chip in the form of an integrated circuit. The semiconductor chips 130 are arranged on a main surface of the printed circuit board 110 that is to be populated. In FIG. 1, the main surface that is to be populated is the top side of the printed circuit board 110.

FIG. 2A shows a plan view of an assemblage of two printed circuit board regions that have not yet been divided and are respectively assigned to an electrical circuit 200, in accordance with one exemplary embodiment of the present disclosure. To put it more precisely, a schematic excerpt from a printed circuit board substrate over two individual substrates that are still in an assemblage is illustrated. A main printed circuit board 210, contact connection pads 215, metalized plated-through holes 220 and electrical lines 225 are shown.

The main printed circuit board 210 illustrated in FIG. 2A has two printed circuit board regions that are respectively assigned to an electrical circuit. The main printed circuit board 210 has a rectangular base area. The main printed circuit board 210 comprises a substrate material such as is known in the field of microelectronics, construction and connection technology. A main surface of the main printed circuit board 210 that is to be populated, said main surface being shown in the plan view in FIG. 2A, has the contact connection pads 215 and the metalized plated-through holes 220, wherein a respective metalized plated-through hole 220 is connected to two contact connection pads 215 by the electrical lines 225.

The metalized plated-through holes 220 are arranged on a separating line (not illustrated) between the two printed circuit board regions. Along the separating line, the main printed circuit board 210 will later be divided into the two electrical circuits 200. The plated-through holes 220 will likewise be divided in the process. The metalized plated-through holes 220 are arranged in a row. Six plated-through holes 220 are illustrated in FIG. 2A. The metalized plated-through holes 220 have a circular profile. The metalized plated-through holes 220 are filled completely with a suitable electrically conductive material as viewed from the shown main surface of the main printed circuit board 210 in FIG. 2A. In order to produce a plated-through hole 220, firstly a passage hole can be drilled into the main printed circuit board 210 or be produced in some other way. Afterward, the passage hole can be provided with a metalization. In this case, at least the wall of the passage hole can be lined with the metalization.

The electrical lines 225 produce an electrical connection between the metalized plated-through holes 220 and the contact connection pads 215. For this purpose, the electrical lines 225 are produced from a suitable electrically conductive material, such as copper, for example. In FIG. 2A, each of the metalized plated-through holes 220 is connected to two contact connection pads 215 by two electrical lines 225. Consequently, FIG. 2A shows a total of 12 contact connection pads 215 connected to the six metalized plated-through holes 220 by means of 12 electrical lines 225. Here in each case six electrical lines 225 and the contact connection pads 215 connected thereto lie on one side of the separating line and are thus assigned to one of the circuits 200. In FIG. 2A, the contact connection pads 215 have a square base area and are produced from a suitable electrically conductive material.

However, it is clear to a person skilled in the art that the number, arrangement and size of the individual features here can be chosen arbitrarily for illustration purposes. For the sake of better clarity, in each case only one contact connection pad 215, one metalized plated-through hole 220 and one electrical line 225 are provided with reference symbols.

FIG. 2B shows a sectional view of the assemblage of the two electrical circuits 200 that have not yet been divided from FIG. 2A. The section runs through the main printed circuit board 210 one of the plated-through holes 220. It can be seen in FIG. 2B that the plated-through hole 220 extends completely through the main printed circuit board 210 and is filled or lined with an electrically conductive material. The conductor tracks 225 and contact connection pads 215 shown in FIG. 2A are not illustrated in FIG. 2B.

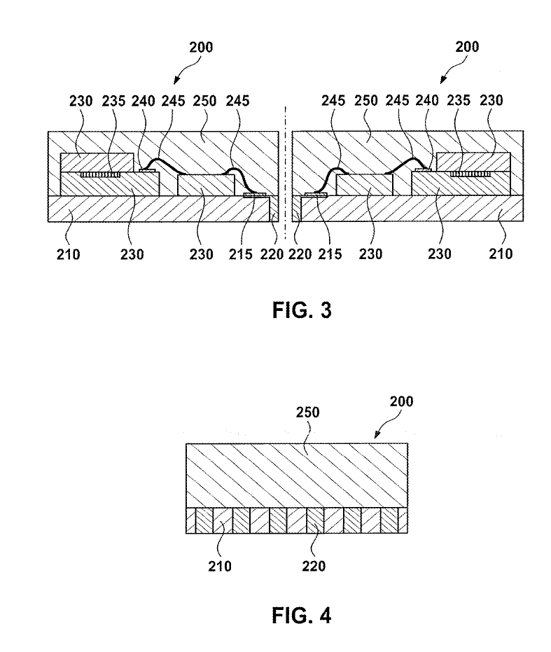

FIG. 3 shows a sectional view of two divided electrical circuits 200 in accordance with one exemplary embodiment of the present disclosure. The electrical circuits 200 can be separated LGA packages. FIG. 3 illustrates a vertical line between the circuits 200, which is the parting line or separating line between the two divided electrical circuits 200. A printed circuit board region of the original printed circuit board 210, a contact connection pad 215, a metalized plated-through hole half 220, semiconductor chips 230, a micromechanical sensor core 235, a chip contact area 240, bonding wires 245 and a potting compound 250 are shown in each of the two divided electrical circuits 200. An arrangement of the individual features of the electrical circuits 200 is substantially symmetrical with respect to the separating line, the metalized plated-through hole halves 220 lying closest to the separating line. Hereinafter, for FIG. 3 a description is given only for one of the two electrical circuits 200 in a representative fashion for the other electrical circuit.

The printed circuit board 210 of the electrical circuit 200 has the contact connection pad 215 and the metalized plated-through hole half 220. The metalized plated-through hole half 220 extends through the printed circuit board 210 from one main surface of the printed circuit board 210 to the other. The metalized plated-through hole half 220 is completely filled with a suitable electrically conductive material. The contact connection pad 215 is connected to the metalized plated-through hole half 220 in an electrically conductive manner by means of an electrical line (not shown in FIG. 3). The metalized plated-through hole half 220 constitutes an external connection contact of the electrical circuit 200. The plated-through hole half 220 was produced by dividing an original plated-through holes in the region of the separating line.

Two semiconductor chips 230 are illustrated in the sectional view in FIG. 3. That one of the semiconductor chips 230 which is arranged respectively further away from the separating line is a typical capacitive inertial sensor known to the person skilled in the art. The semiconductor chip or inertial sensor chip 230 is connected to the second, individually arranged semiconductor chip 230 by means of the chip contact area 240 and a bonding wire 245. The bonding wire 245 produces an electrical connection between the chip contact area 240 and the individually arranged semiconductor chip 230. A further bonding wire 245 produces an electrical connection between the individually arranged semiconductor chip 230 and the contact connection pad 215 of the printed circuit board 210.

The potting compound 250 encapsulates or overmolds the electrical circuit 200 on the side of the printed circuit board 210 on which the semiconductor chips 230, the contact connection pad 215, the chip contact area 240 and the bonding wires 245 are arranged.

A description is given below of how, in the context of a production process, it is possible to obtain an assemblage of electrical circuits, for example the assemblage shown in FIGS. 2A and 2B, and therefrom an individual electrical circuit such as is shown in FIG. 3, for example. An electrical circuit 200 or an LGA package consists of a printed-circuit-board-based substrate, onto which the semiconductor chips are usually adhesively bonded and contact-connected in a wire-bonded manner. This arrangement is then overmolded with a potting compound 250 or epoxy compound for protection purposes. In a chip placement and transfer molding process, the substrates are still connected to one another as the main printed circuit board 210. After the molding process, the board is sawn into the individual systems. By virtue of this board/array arrangement, the production process is very efficient and the LGA package is very cost-effective. The printed circuit board substrate can be metalized merely in a single-layered fashion. The contact connection pads 215, or contact pads, onto which wire bonding is effected, are situated on the top side, which is encapsulated or overmolded later. Said pads are electrically connected to metalized plated-through holes at the edge side of the main printed circuit board 210 by means of electrical lines 225 or copper conductor tracks. The metalized plated-through holes 220 on the edge side establish the mechanical and electrical contact of the electrical circuit 200 or of the LGA package toward the outside.

In the case of the present disclosure, the main printed circuit boards 210 or substrates are designed such that all external connections lie on an edge side of the printed circuit board regions 210 or of the substrate of the later electrical circuit. The external connections of the electrical circuit 200 are no longer embodied as planar soldering pads on the underside of the substrate, as is known for an LGA, but rather as metalized plated-through holes 220 on the side area of the main printed circuit board 210 from the top side of the substrate to the underside of the substrate. The substrates can be embodied with metal layers only on one side. On the substrate board or the array, two adjacent individual packages initially still respectively share the plated-through holes. The plated-through holes in the substrate can be completely metalized, preferably with copper material, which is used as standard in printed circuit board production. After the customary placement and molding process, the array is separated in a process that involves sawing through the plated-through holes. In this case, the individual packages additionally have to be provided with a solderable metalization, e.g. chemical nickel:gold, on the severed through contacts after the dividing or separating or sawing. This gives rise to electrical circuits 200 in the form of individual LGA packages with semicylindrical contacts on one side.

FIG. 4 shows a side view of an electrical circuit 200 in accordance with one exemplary embodiment of the present disclosure. The electrical circuit 200 is one of the two electrical circuits 200 from FIG. 3. FIG. 4 shows the side surface of the electrical circuit 200 on which the metalized plated-through hole halves 220 are arranged. This is, for example, a view, from the side, of an LGA package (sawing section) with plated-through hole halves 220 on the side.

From the electrical circuit 200, FIG. 4 in this case illustrates a lower region with alternating sections of the printed circuit board 210 and of the metalized plated-through hole halves 220 and an upper region with the potting compound 250. In this case, FIG. 4 shows seven sections of the printed circuit board 210, between which are arranged six sections each having a metalized plated-through hole half 220. In this case, the sections alternate with one another in a horizontal direction in FIG. 4. In this case, the metalized plated-through hole halves 220 each extend through the entire thickness of the printed circuit board 210, that is to say between an upper area and a lower area of the printed circuit board 210. Corresponding plated-through hole halves 220 can be arranged on one or a plurality of side edges of the printed circuit board 210.

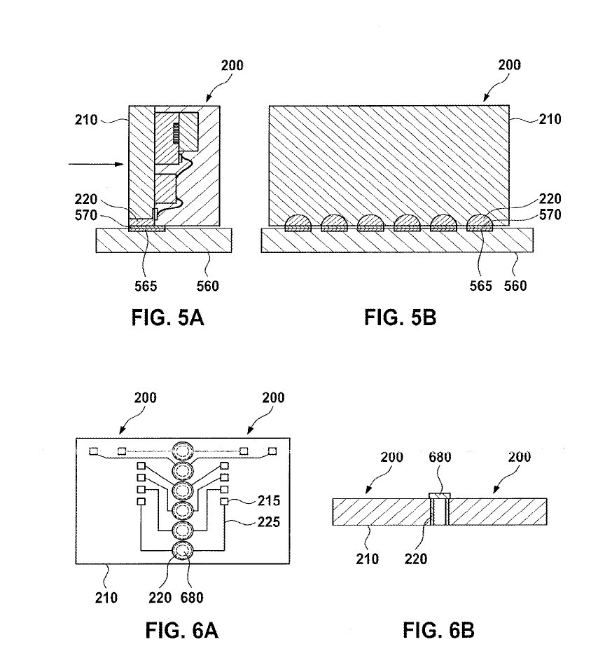

FIGS. 5A and 5B in each case show a sectional view of a carrier substrate 560 and of an electrical circuit 200 fitted thereto in accordance with one exemplary embodiment of the present disclosure. The electrical circuit 200 is one of the two electrical circuits 200 from FIG. 3, or the electrical circuit 200 from FIG. 4. In this case, on the carrier substrate 560, connection contacts 565 are additionally shown, as is a solder material 570, which connects the electrical circuit 200 to the carrier substrate 560.

In FIG. 5A, that part of the sectional view which shows the electrical circuit 200 corresponds to the view of one of the two electrical circuits 200 from FIG. 3, although the view is rotated by 90° in the clockwise direction in the case of the left-hand circuit from FIG. 3 and is rotated by 90° in the counterclockwise direction in the case of the right-hand circuit from FIG. 3. The electrical circuit 200 is fitted to the carrier substrate 560 by means of the solder material 570 between the metalized plated-through hole 220 and the connection contact 565. In this case, a main extension plane of the printed circuit board 210 electrical circuit 200 runs substantially orthogonally with respect to a main extension plane of the carrier substrate 560.

In FIG. 5B, the view from FIG. 5A is merely rotated such that the viewing direction corresponds to the part illustrated in FIG. 5A. Consequently, that main surface of the printed circuit board 210 of the electrical circuit 200 is shown on which no encapsulated semiconductor components are arranged. In the view from FIG. 5B, it can be discerned that the electrical circuit 200 is fitted to a respective one of the connection contacts 565 at each of its metalized plated-through holes 220 by means of the solder material 570. FIG. 5B illustrates by way of example six metalized plated-through holes 220, six connection contacts 565 and six sections composed of the solderable material 570.

The metalized plated-through holes 220 in the form of the semicylindrical contacts constitute the soldering areas for orthogonally soldering the electrical circuit 200 or the LGA package thereon and are suitable for a standard soldering process. By way of the substrate thickness of the printed circuit board 210, it is possible to set the length of the contact-connection and hence the mechanical stability of the soldering connection. Consequently, the illustration shows orthogonal mounting of the electrical circuit 200 or of the LGA package onto the carrier substrate 560 by means of the solder material 570.

FIG. 6A shows a plan view and FIG. 6B shows a sectional view of an assemblage of two printed circuit board regions that have not yet been divided and are respectively assigned to an electrical circuit 200, in accordance with one exemplary embodiment of the present disclosure. In this case, the assemblage of electrical circuits 200 as illustrated in FIG. 6A corresponds to that from FIG. 2A apart from the fact that the metalized plated-through holes 220 are in each case covered by a covering 680. The coverings 680 can cover the metalized plated-through holes 220 to a large extent or else go beyond the latter. In this case, the assemblage of electrical circuits 200 as illustrated in FIG. 6B corresponds to that in FIG. 2B apart from the fact that the metalized plated-through hole 220, as can be discerned here, is filled incompletely and the cavity present, which extends along the entire longitudinal direction of the metalized plated-through holes 220, is closed at one end by the covering 680.

A description is given below of how, in the context of a production process, an assemblage of electrical circuits such as this of the two electrical circuits 200 from FIG. 2A and FIG. 2B can be processed further in order to obtain the assemblage of electrical circuits 200 as shown in FIGS. 6A and 6B. The metalized plated-through holes 220 are metalized with copper material only at the edge and their surface is already provided with a solderable metalization (e.g. chemical nickel:gold) in the standard production process for the printed circuit board. In order that no potting compound 250 or molding compound flows into the plated-through holes during the encapsulating or molding process, the plated-through holes, at the end of the printed circuit board production process, on the substrate top side of the main printed circuit board 210, are closed with a suitable material, e.g. with a patternable solid resist or a film-like resist layer or some other material known from printed circuit board manufacture. Accordingly, a covering of the edge-metalized plated-through holes with solid resist is carried out.

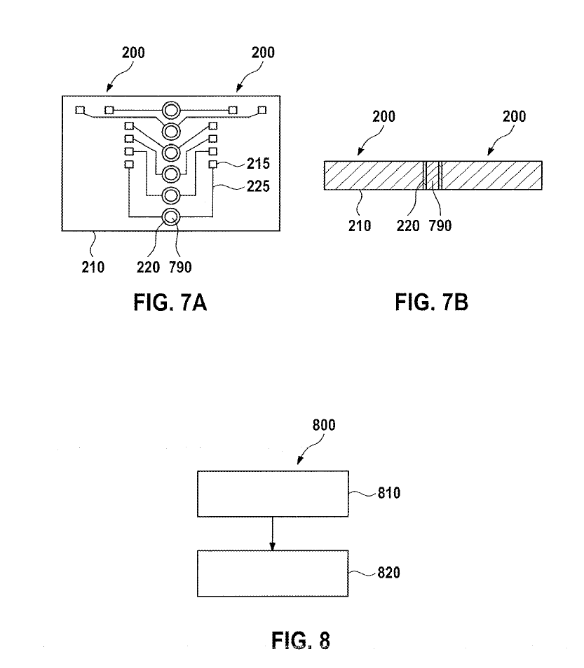

FIG. 7A shows a plan view and FIG. 7B shows a sectional view of an assemblage of two printed circuit board regions that have not yet been divided and that are respectively assigned to an electrical circuit 200, in accordance with one exemplary embodiment of the present disclosure. In this case, the assemblage of electrical circuits 200 as illustrated in FIG. 7A corresponds to that from FIG. 2A apart from the fact that the metalized plated-through holes 220 are in each case filled by a temporary material 790. In this case, the temporary material 790 fills a respective cavity in each of the metalized plated-through holes 220. In this case, the assemblage of electrical circuits 200 as illustrated in FIG. 7B corresponds to that from FIG. 2B apart from the fact that the metalized plated-through hole 220, as can be discerned here, is metalized incompletely and the cavity present, which extends along the entire longitudinal direction of the metalized plated-through holes 220, is filled with the temporary material 790.

A description is given below of how, in the context of a production process, an assemblage of electrical circuits such as this of the two electrical circuits 200 from FIG. 2A and FIG. 2B can be processed further in order to obtain the assemblage of electrical circuits 200 as shown in FIGS. 7A and 7B. The metalized plated-through holes 220 are metalized with copper material only at the edge and their surface is already provided with a conductive metalization (e.g. chemical nickel:gold) in the standard production process for the printed circuit board. In order that no potting compound 250 or molding compound flows into the plated-through holes during the encapsulating or molding process, the plated-through holes, at the end of the printed circuit board production process, are filled with a temporary material. Said temporary material can be removed again during the standardized post-mold cure process or after molding, e.g. before or during sawing. In one embodiment variant, the temporary material decomposes into gaseous products without any residues at relatively high temperatures (see e.g. thermally decomposable polymer from Promerus). A material that dissolves in water during the sawing process is also conceivable. Therefore, edge-metalized plated-through holes are filled with a temporary material.

Alternatively, the plated-through holes on the substrate top side of the main printed circuit board 210 can be completely metalized or filled, although the degree of filling of the metalization decreases in the direction of the substrate underside of the main printed circuit board 210, such that the substrate underside is only edge-metalized.

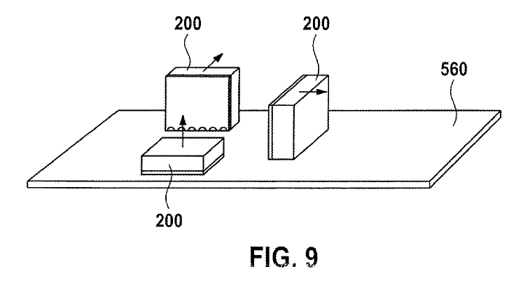

FIG. 8 shows a flow chart of a method 800 for producing an electrical circuit, in accordance with one exemplary embodiment of the present disclosure. The method 800 comprises a step 810 of providing a main printed circuit board having a plurality of printed circuit board regions each having contact connection pads on at least the main surface of the printed circuit board region that is to be populated, a plurality of metalized plated-through holes along a separating line of the printed circuit board region, electrical lines for connection between the plurality of plated-through holes and the contact connection pads, and at least one semiconductor chip which is fitted to the main printed circuit board in the printed circuit board region and is electrically contact-connected by means of the contact connection pads. The method 800 furthermore comprises a step 820 of dividing the main printed circuit board along at least one separating line of the plurality of printed circuit board regions, such that the plurality of metalized plated-through holes are divided by the process of dividing 820 the main printed circuit board, in order to form external connections of the electrical circuit.

FIG. 9 shows a schematic illustration of a 3-axis sensor module in accordance with one exemplary embodiment of the present disclosure. The sensor module has a carrier substrate 560, on which three sensor circuits 200 are arranged. In this case, a first of the sensor circuits 200 is arranged directly on a surface of the carrier substrate 560. Another two of the sensor circuits 200 are mounted by an edge region onto the surface of the carrier substrate 560, such that the printed circuit boards of the sensor circuits 200 are oriented orthogonally with respect to one another and orthogonally with respect to the carrier substrate 560. The perpendicularly positioned sensor circuits 200 can have in edge regions plated-through hole halves via which they are both electrically and mechanically connected to the carrier substrate 560. If the sensor circuits 200 are acceleration sensors or rate-of-rotation sensors, for example, then the sensor module can be used to measure linear accelerations or angular accelerations in the three sensing directions that are orthogonal to one another and are indicated by the arrows.

In accordance with one exemplary embodiment, the present disclosure provides a printed circuit board having plated-through holes at the edge of the printed circuit board. The plated-through holes are—at least in partial regions—metalized, electrically conductive, and also continuous in the printed circuit board as far as the interface between printed circuit board and molding compound. The plated-through holes are shared with an adjacent system. A separating line runs centrally through the plated-through holes. The steps of molding, separating and soldering take place at the plated-through holes.

A metalization or the plated-through holes can have the form of a circle or ring segment (“edge-filled”). The printed circuit board has a solderable surface at the plated-through holes.

A temporary filling can be effected prior to molding.

Furthermore, a covering can be effected prior to molding.

The plated-through holes can have the form of a circle segment (completely filled) and the plated-through hole surface can be metalized in a solderable manner after separation.

The exemplary embodiments described and shown in the figures have been chosen merely by way of example. Different exemplary embodiments can be combined with one another completely or with regard to individual features. Moreover, one exemplary embodiment can be supplemented by features of a further exemplary embodiment. Depending on what preprocessing has already been effected or what postprocessing is additionally intended to be effected, the method for producing an electrical circuit can also comprise only one method step or individual method steps from among the method steps described with reference to the figures.

What is claimed is:

1. A method for producing an electrical circuit, comprising:
providing a main printed circuit board having a plurality of metalized plated-through holes through the main printed circuit board along at least one separating line between adjacent printed circuit board regions of the main printed circuit board, wherein each printed circuit board region has electrical contact connection pads on at least the main surface of the printed circuit board region that is to be populated, electrical lines for connection between the plurality of plated-through holes and the contact connection pads, and at least one semiconductor chip (230) electrically contact-connected by the contact connection pads, wherein the main printed circuit board is covered with a potting compound across the printed circuit board regions with the semiconductor chips; and
dividing the main printed circuit board along the at least one separating line, wherein the plated-through holes are divided along the separating line in order to form external connections of the electrical circuit.

2. The method according to claim 1, wherein dividing is effected such that metalized plated-through hole segments extending over an entire thickness of the main printed circuit board in each case remain at printed circuit board regions adjacent to a separating line.

3. The method according to claim 2, wherein the metalized plated-through holes are completely filled with an electrically conductive material, such that the plated-through hole segments in each case have the form of a circle segment, further comprising:
applying a solderable material to the plated-through hole segments after the step of dividing.

4. The method according to claim 2, wherein, in the step of providing, a solderable material is used for forming the plurality of metalized plated-through holes and the metalized plated-through holes are shaped in a ring-shaped fashion, such that the plated-through hole segments in each case have the form of an annulus segment.

5. The method according to claim 4, wherein, in the step of providing, a temporary filling material is filled into the plurality of metalized plated-through holes or a covering of the plurality of metalized plated-through holes is formed on the side of the main surface of the main printed circuit board that is to populated with the contact connection pads before the printed circuit board regions with the semiconductor chips are covered with the potting compound.

6. An electrical circuit, comprising:
a printed circuit board, which has electrical contact connection pads on at least the main surface of the printed circuit board that is to be populated, a plurality of metalized plated-through hole segments along an edge area of the printed circuit board for forming external connections of the electrical circuit and electrical lines for connection between the plurality of plated-through hole segments and the contact connection pads of the printed circuit board;
at least one semiconductor chip, which is fitted to the main surface of the printed circuit board that is to be populated, and is electrically contact-connected by the contact connection pads; and
a potting compound, which covers the printed circuit board across the semiconductor chip.

7. The electrical circuit according to claim 6, wherein the at least one semiconductor chip has a sensor element.

8. A sensor module, comprising:
an electrical circuit, comprising:
a printed circuit board, which has electrical contact connection pads on at least the main surface of the printed circuit board that is to be populated, a plurality of metalized plated-through hole segments along an edge area of the printed circuit board for forming external connections of the electrical circuit and electrical lines for connection between the plurality of plated-through hole segments and the contact connection pads of the printed circuit board;
at least one semiconductor chip, which is fitted to the main surface of the printed circuit board that is to be populated, and is electrically contact-connected by the contact connection pads; and
a potting compound, which covers the printed circuit board across the semiconductor chip; and
a carrier substrate with connection contacts,
wherein the plurality of plated-through hole segments are electrically and mechanically connected to the connection contacts of the carrier substrate, and wherein the main surface of the printed circuit board of the at least one electrical circuit is oblique or orthogonal with respect to a main surface of the carrier substrate.

9. A method for producing a sensor module, comprising the following steps:
providing a carrier substrate with connection contacts;
providing at least one electrical circuit, comprising:
a printed circuit board, which has electrical contact connection pads on at least the main surface of the printed circuit board that is to be populated, a plurality of metalized plated-through hole segments along an edge area of the printed circuit board for forming external connections of the electrical circuit and electrical lines for connection between the plurality of plated-through hole segments and the contact connection pads of the printed circuit board;
at least one semiconductor chip, which is fitted to the main surface of the printed circuit board that is to be populated, and is electrically contact-connected by the contact connection pads; and
a potting compound, which covers the printed circuit board across the semiconductor chip; and
soldering the plurality of plated-through hole segments of the at least one electrical circuit with the connection contacts of the carrier substrate,
wherein the main surface of the printed circuit board of the at least one electrical circuit is oblique or orthogonal with respect to a main surface of the carrier substrate.
